(19) United States
(12) Patent Application Publication
(10) Pub. No.: US 2024/0321651 A1
(43) Pub. Date: Sep. 26, 2024

(54) SEMICONDUCTOR DEVICES WITH INTEGRATED TEST STRUCTURES

(71) Applicant: Woflspeed, Inc., Durham, NC (US)

(72) Inventors: Rahul R. Potera, Apex, NC (US); In-Hwan Ji, Apex, NC (US)

(21) Appl. No.: 18/125,610

(22) Filed: Mar. 23, 2023

(51) Int. Cl. H01L 21/66; G01R 31/26; H01L 21/04; H01L 29/06; H01L 29/16; H01L 29/66; H01L 29/872

(52) U.S. Cl. CPC H01L 22/32; G01R 31/2632; G01R 31/2644; H01L 21/046; H01L 29/0623; H01L 29/1608; H01L 29/6606; H01L 29/872

(57) ABSTRACT

A semiconductor device includes a semiconductor layer having a first area and an edge termination area outside the first area. The semiconductor layer has a first conductivity type, an active area in the first area, a test area in the first area adjacent the active area, a first anode contact on the semiconductor layer in the active area, a second anode contact on the semiconductor layer in the test area, and a cathode contact in electrical contact with the semiconductor layer. A related method of testing surge current capability of a semiconductor device includes applying a forward current that is smaller than a maximum forward current of the semiconductor device to a test active area that is within an area inside a main edge termination area of the semiconductor device, and detecting a failure of the semiconductor device in response to the forward current.

### BACKGROUND

The present disclosure relates to semiconductor device structures and in particular to power semiconductor devices including silicon carbide Schottky diodes and metal-oxide semiconductor field effect transistors (MOSFETs).

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H—SiC at room temperature) and the Group Ill nitrides (e.g., 3.36 eV for GaN at room temperature). These materials may have higher electric field breakdown strengths and higher electron saturation velocities than GaAs and Si.

One important application for wide bandgap semiconductors such as silicon carbide is in Schottky diodes.

A Schottky diode, also known as Schottky barrier diode, is a semiconductor diode formed by the junction of a semiconductor with a metal. The metal-semiconductor junction (instead of a semiconductor-semiconductor junction as in conventional PN-junction diodes) in a Schottky diode creates a Schottky barrier. The metal side acts as the anode, and an n-type semiconductor acts as the cathode of the diode. When sufficient forward voltage is applied to overcome the Schottky barrier of the metal-semiconductor junction, current flows through the device in the forward direction. When a reverse voltage is applied, a depletion region is formed in the semiconductor, obstructing current flow.

Compared to a conventional PN-junction diode, a Schottky diode has a low forward voltage drop and a very fast switching action.

An important difference between a PN-junction diode and a Schottky diode is the reverse recovery time (tᵣᵣ), which it the time it takes of the diode to switch from a conducting (forward biased) state to a non-conducting (reverse biased) state. In the conducting state, a conventional PN-junction diode injects minority carriers into the diffusion region on the N-side of the junction where they recombine with majority carriers after diffusion. The reverse recovery time of a PN-junction is primarily limited by the diffusion capacitance of minority carriers accumulated in the diffusion region during the conducting state.

In contrast, a Schottky diode is a unipolar or “majority carrier” device that does not rely on minority carrier injection. Rather, in the conducting state, majority carriers (electrons in the case of an n-type semiconductor layer) are injected across the junction. Thus, switching a Schottky diode from a conducting to a non-conducting state does not require time for recombination of the injected carriers. Rather, the switching speed of a Schottky diode is only limited by the junction capacitance of the device.

Silicon carbide Schottky diodes are the rectifiers of choice in advanced power electronics at 650V and above, primarily because they achieve fast switching speeds with much lower leakage current and capacitance than silicon-based Schottky diodes.

### SUMMARY

A semiconductor device according to some embodiments includes a semiconductor layer including a first area and an edge termination area outside the first area, wherein the semiconductor layer has a first conductivity type, an active area in the first area, a test area in the first area adjacent the active area, a first anode contact on the semiconductor layer in the active area, a second anode contact on the semiconductor layer in the test area, and a cathode contact in electrical contact with the semiconductor layer.

The active area may include a first plurality of junction shielding regions in the semiconductor layer, the first plurality of junction shielding regions having a second conductivity type opposite the first conductivity type, and the first anode contact may contact the semiconductor layer and the first plurality of junction shielding regions.

In some embodiments, the test area includes a second plurality of junction shielding regions in the semiconductor layer, wherein the second anode contact contacts the semiconductor layer and the second plurality of junction shielding regions.

The semiconductor layer may include an n-type semiconductor material, and the first plurality of junction shielding regions may include p-type semiconductor areas.

In some embodiments, the edge termination area is a main edge termination area, and the semiconductor device further includes a test edge termination area outside the test area, wherein the test edge termination area is within the first area.

The test edge termination area may include a plurality of concentric rings of implanted regions having a second conductivity type, opposite the first conductivity type.

In some embodiments, the spacing between adjacent ones of the plurality of concentric rings is non-uniform. The spacing between adjacent ones of the plurality of concentric rings may be greater in a middle portion of the test edge termination area and smaller in first portions of the test edge termination area near the active area and second portions of the test edge termination area near the test area.

The semiconductor device may further include a conductive electrical connection between the first anode contact and the second anode contact. The conductive electrical connection may include a wirebond and/or a metal layer.

The first area may have a generally rectangular shape, and the test active area may be located near a corner of the first area or near a middle of a side of the first area.

The semiconductor device may further include an isolation ring around the test area. The isolation ring may include a region of the semiconductor layer having the first conductivity type.

The semiconductor device may include a Schottky diode device or a metal-oxide semiconductor field effect transistor device.

A method of manufacturing a semiconductor device incudes forming an edge termination area in a semiconductor layer, wherein the edge termination area is outside a first area of the semiconductor layer, wherein the semiconductor layer has a first conductivity type, forming an active area in the first area, forming a test area (50A) in the first area adjacent the active area, forming a first anode contact on the semiconductor layer in the active area, forming a second anode contact on the semiconductor layer in the test area, and forming a cathode contact in electrical contact with the semiconductor layer.

The method may further include forming a first plurality of junction shielding regions in the semiconductor layer, the first plurality of junction shielding regions having a second conductivity type opposite the first conductivity type. The first anode contact may contact the semiconductor layer and the first plurality of junction shielding regions.

The method may further include forming a second plurality of junction shielding regions in the semiconductor layer in the test area. The second anode contact may contact the semiconductor layer and the second plurality of junction shielding regions.

A method of testing surge current capability of a semiconductor device according to some embodiments includes applying a forward current that is smaller than a maximum forward current of the semiconductor device to a test active area that is within an area inside by a main edge termination area of the semiconductor device, and detecting a failure of the semiconductor device in response to the forward current.

In some embodiments, the semiconductor device has an edge termination area outside the main active area, and the test active area is in an area inside the edge termination area.

In some embodiments, the forward current is applied to the test active area for a predetermined time period. A level of the forward current is selected based on a ratio of an area of the test active area to an area of the main active area and based on a rated operating current of the main active area.

The semiconductor device may include a Schottky diode device or a metal-oxide semiconductor field effect transistor device.

### BRIEF DESCRIPTION OF THE DRAWINGS

FIG. 1 illustrates a Schottky diode according to some embodiments.

FIGS. 2A and 2B are plan views of a Schottky diode in accordance with some embodiments.

FIG. 3 is a cross section of a portion of a Schottky diode in accordance with some embodiments.

FIG. 4A is a plan view of a Schottky diode in accordance with some embodiments.

FIG. 4B is a cross section of a portion of a Schottky diode in accordance with some embodiments.

FIGS. 5, 6 and 7 are plan views of Schottky diodes in accordance with various embodiments.

FIG. 8 illustrates operations for forming a Schottky diode according to some embodiments.

FIG. 9 is a flowchart illustrating operations for testing a Schottky diode according to some embodiments.

### DETAILED DESCRIPTION OF EMBODIMENTS

Embodiments of the inventive concepts will now be described in connection with the accompanying drawings.

Silicon carbide Schottky diodes are well suited for use in advanced power electronics at voltages of 650V and above, primarily because they achieve fast switching speeds with much lower leakage current and capacitance than silicon Schottky diodes. In power supply boost convertors, a SiC Schottky diode is required to carry a surge current of about 10-15× the rated current for a short interval of several milliseconds. So-called MPS (Merged PN-Schottky) diodes accomplish this by merging islands of P-N junctions into the Schottky diode so that at high forward currents, the P-N junction can turn on, which enables conductivity modulation of the drift layer and allows the device to conduct surge current at lower voltages than conventional Schottky diodes.

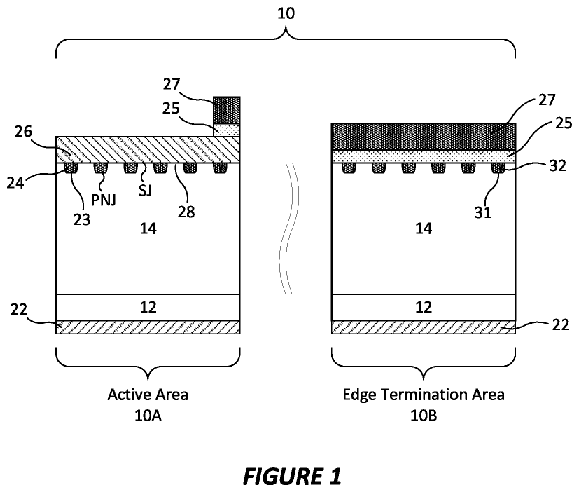

An MPS Schottky diode 10 is illustrated in cross-section in FIG. 1. The Schottky diode 10 includes an active area 10A and an edge termination area 10B (also called a junction termination region, or simply a termination region) that is outside the active area 10A. Although the active area 10A and the edge termination area 10B are shown in FIG. 1 as separate regions for ease of illustration, it will be appreciated that they are part of the same device.

An n-silicon carbide epitaxial layer 14 is formed on a silicon carbide substrate 12. A metal anode contact 26 is formed on the surface of the silicon carbide epitaxial layer 14 opposite the substrate 12. The anode contact 26 forms a Schottky barrier junction SJ with the silicon carbide epitaxial layer 14.

At the surface of the silicon carbide epitaxial layer 14, a plurality of p+ junction shielding regions 24 are formed at the surface of the silicon carbide epitaxial layer 14. The p+ junction shielding regions 24 may be formed by ion implantation to form P-N junctions PNJ with the silicon carbide epitaxial layer 14. A cathode ohmic contact 22 is formed on the back side of the substrate 12. The anode contact 26 forms ohmic contact to the p+ junction shielding regions 24. Although described in terms of a device including an n-type epitaxial layer 14 and p-type junction shielding regions 24, it will be appreciated that in some embodiments the conductivity types may be reversed, i.e., a p-type epitaxial layer with n-type shielding regions.

The Schottky barrier junction SJ between the anode contact 26 and the silicon carbide epitaxial layer 14, which is formed on exposed regions 28 of the silicon carbide epitaxial layer 14 between the p+ junction shielding regions 24, has a lower barrier energy than the P-N junctions PNJ between the p+ junction shielding regions 24 and the silicon carbide epitaxial layer 14. This allows the Schottky barrier junction SJ to turn on before the P-N junctions PNJ in the forward biased (conducting) state. Conversely, in the reverse biased (non-conducting) state, the Schottky barrier junction SJ is shielded from high electric fields by the depletion region formed at the interface of the P-N junctions PNJ and the silicon carbide epitaxial layer 14.

In the edge termination area 10B, a plurality of floating guard rings 32 (also called equipotential rings or field rings) are formed in respective regions 31 at the surface of the silicon carbide epitaxial layer 14. The guard rings 32 may comprise implanted p+ regions in the silicon carbide epitaxial layer 14. A silicon nitride passivation layer 25 is formed over the edge termination area 10B and extends onto the anode contact 26 in the active area 10A. A protective layer 27 of a material such as polyimide is formed on the silicon nitride passivation layer 25.

The performance of a Schottky diode device under surge current conditions may be difficult to verify at the wafer sort level of production, and even after device packaging, since large currents are required to be measured. For example, a 1200V diode rated at 50 A of forward current must be tested for surge current capability using a current pulse of more than 500 A for a time of at least about 10 ms. Such high currents are not easily generated by automated production testers. Currently, to perform surge current testing of high power semiconductor devices (such as semiconductor devices capable of blocking voltages in excess of 650 V), it is typical to perform a current surge test on a single die from a wafer (referred to as a process control monitoring, or PCM, die). However, due to variations in process conditions and materials, individual dies on a wafer may have different current characteristics. Thus, the test on the PCM die may not be fully representative of the performance of all devices on the wafer. The PCM die also uses valuable space on the wafer that is then unavailable for use in a usable device.

Some embodiments provide MPS Schottky diode structures with high current ratings that can be tested for surge current performance at relatively low current levels. In particular, some embodiments provide a Schottky diode structure including an integrated test structure. The device can be tested by applying an equivalent current density of surge current to an anode test pad of the integrated test structure. The surge performance of the device can be evaluated at significantly lower currents, which allows the device to be tested on production tester equipment, such as during a wafer sort procedure. The anode test pad is provided within the active area of the device and may contribute only a small amount to the overall die size for large die-size devices.

Some particular embodiments may be used in large area silicon carbide Schottky diodes to enable in-situ test of 10 ms surge capability. The ability to perform such testing enables a manufacturer of the device to state a maximum specification of surge current capability. Currently, the maximum 10 ms surge specification cannot be guaranteed for SiC Schottky diodes. For applications such as boost converters and other applications where surge performance is critical, the ability to state a maximum surge current capability would provide a competitive advantage to the manufacturer.

In particular, some embodiments described herein enable the testing of surge current on the anode test pad of the die at a substantially lower current than would be necessary to test the full size die under surge conditions. That is, a single die may be tested by passing a test surge current through the anode test pad of the die. The test surge current is smaller than the surge current of the full die. The surge current capability of the full die is correlated with and can be inferred from the test surge current as described below. Accordingly, some embodiments also enable testing of each individual die on a wafer, instead of only testing a single PCM die.

The surge current capability of different devices varies between die primarily because the contact resistance of the anode metal to the p+ implanted region in the device may vary considerably across the wafer, especially when dedicated ohmic contact processes are not used. This variation changes the voltage at which the PN junction starts to conduct and modulate the conductivity of the drift region.

The surge current capability may also vary from device to device because the thermal impedance of the die, driven primarily by thermal conductance of the backside die-attach, may vary from device to device. This changes the temperature rise in the device due to self-heating in the device under surge conditions.

Variation in surge performance can be mitigated by testing the surge capability of the die at the wafer sort level and after packaging. However, as noted above, 10 ms surge testing typically requires about 10 times the rated current of the device, and so would require 500A for a 50A device having overall dimensions of about 5 mm×5 mm with an active region area of about 20 μm².

The surge current of the test device is calculated by multiplying the ratio of the test area to the main area by the desired surge current level. Thus, by integrating a test anode pad with a smaller active area (e.g., 400 μm×400 μm or 0.16 μm² area) within the device, the test device only needs to be driven to about 4A to reach surge conditions, since (0.16 μm^{2/20} μm²)×500 A=4 A. This level of current can be achieved in-line in a process control monitoring test at wafer sort, or at final test using production testers. Thus, some embodiments may enable the performance of a test of a Schottky diode device during manufacturing of 10 ms surge performance.

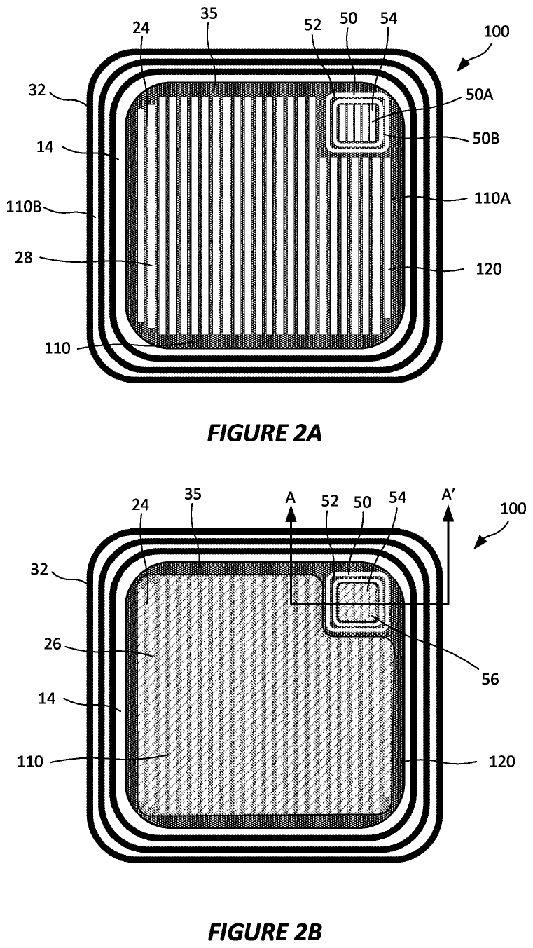

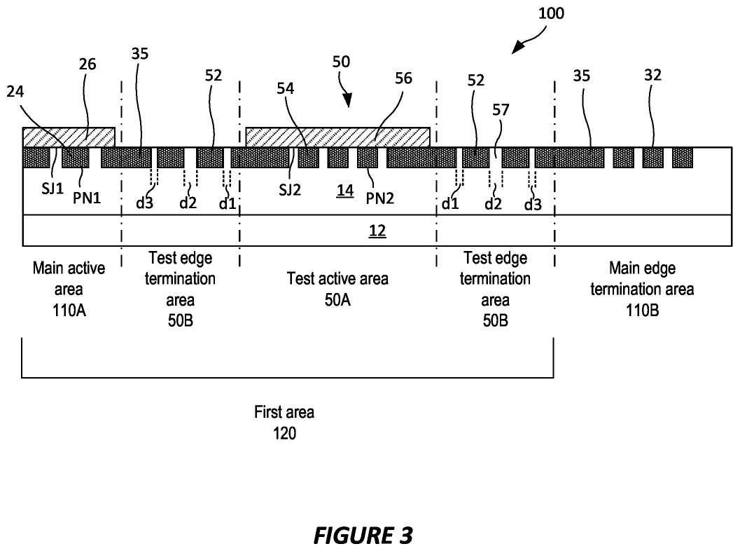

FIGS. 2A and 2B are plan views of a Schottky diode 100 including a main Schottky diode device 110 and an integrated test structure 50 according to some embodiments, and FIG. 3 is a cross sectional view taken along line A-A′ of FIG. 2B. FIG. 2A illustrates the Schottky diode 100 without Schottky metallization for clarity of illustration, and FIGS. 2B and 3 illustrate the Schottky diode 100 with Schottky metallization. In an example embodiment, the Schottky diode 100 may be formed in SiC and have overall dimensions of about 5 mm×5 mm, and may have a reverse voltage blocking rating of 1200V and a forward current rating of 50A, although the inventive concepts described herein are applicable to devices having other dimensions and/or voltage/current ratings.

Referring to FIG. 2A, the Schottky diode 100 includes a semiconductor epitaxial layer 14 including a first area 120 that is inside a main edge termination area 110B. The semiconductor epitaxial layer 14 may, for example, comprise silicon carbide. A main active area 110A is defined within the first area 120. The first area 120 may have a generally rectangular shape, although other shapes are possible. The main edge termination area 110B, which is outside the first area 120, includes a plurality of concentric floating guard rings 32. However, it will be appreciated that different edge termination structures may be provided in the main edge termination area 110B.

An implanted well region 35 is formed within the main active area 110A. The implanted well region 35 may comprise a p+ implanted region that is patterned to form a plurality of p+ junction shielding regions 24 that form the second junctions PNJ described above in connection with FIG. 1. Still referring to FIG. 2A, the integrated test structure 50 is formed within the first area (i.e. inside the periphery of the edge termination area 110B). The integrated test structure 50 includes a test active area 50A inside a test edge termination area 50B. The test active area 50A includes a plurality of p+ regions 54 at the surface thereof. The test edge termination area 50B includes a plurality of concentric floating guard rings 52 that are outside the test active area 50A. The p+ regions 54 in the integrated test structure 50 may be formed via ion implantation in a same ion implantation process as is used to form the p+ junction shielding regions 24, so that the p+ regions 54 in the integrated test structure 50 have substantially the same doping profile as the p+ junction shielding regions 24.

Referring to FIGS. 2B and 3, a main anode contact 26 is formed on the epitaxial layer 14 in portions of the main active area 110A over the well region 35 other than over the integrated test structure 50. The main anode contact 26 forms a first Schottky junction SJ1 with the silicon carbide layer epitaxial 14 in exposed regions of the epitaxial layer 14 between the p+ junction shielding regions 24. A test anode contact 56 is formed on the on the epitaxial layer 14 in the test active area 50A. The test anode contact 56 forms a second Schottky junction SJ2 with the epitaxial layer 14 in exposed regions 28 of the epitaxial layer 14 between the p+ regions 54 and forms ohmic contact to the p+ regions 54.

Referring to FIG. 3, the floating guard rings 52 in the test edge termination area 50B may be formed as concentric p+ implanted rings. The floating guard rings 52 may provide field termination between the main active area 110A of the main Schottky device 110 and the active area 50A of the integrated test structure 50.

In some embodiments, the floating guard rings 52 may be formed to have a non-uniform spacing therebetween, similar to the guard rings 32. In some embodiments, the spacing between the floating guard rings 52 may be narrower (e.g., about 1 μm) nearer to both the main active area 110A and the test active area 50A, and wider (e.g., 2-3 μm) in the middle of the test edge termination area 50B. For example, as shown in FIG. 3, a spacing d1 between floating guard rings 52 near the test active area 50A may be smaller than a spacing d2 between floating guard rings 52 farther from the test active area 50A. Likewise, a spacing d3 between floating guard rings 52 and the well region 35 of the main active area 110A may be smaller than a spacing d2 between floating guard rings 52 farther from the main active area 110A.

The non-uniform spacing between the floating guard rings 52 can be provided to allow each of the main pad active area 110A and the test active area 50A to block reverse (cathode-anode) voltages, both separately and together. Thus, this design allows the test active area 50A to block reverse voltage even when the main anode contact 26 is floating. Additionally, if the test anode contact 56 is damaged during testing, then the test anode contact 56 may be blocked from operation of the main Schottky diode 110 without premature breakdown from the anode of the main Schottky diode 110 towards the test anode contact 56. As another advantage, surge testing on the test anode contact 56 will restrict surge current to PN junctions in the test active area 50A, thus approaching area scaling of surge capability more closely.

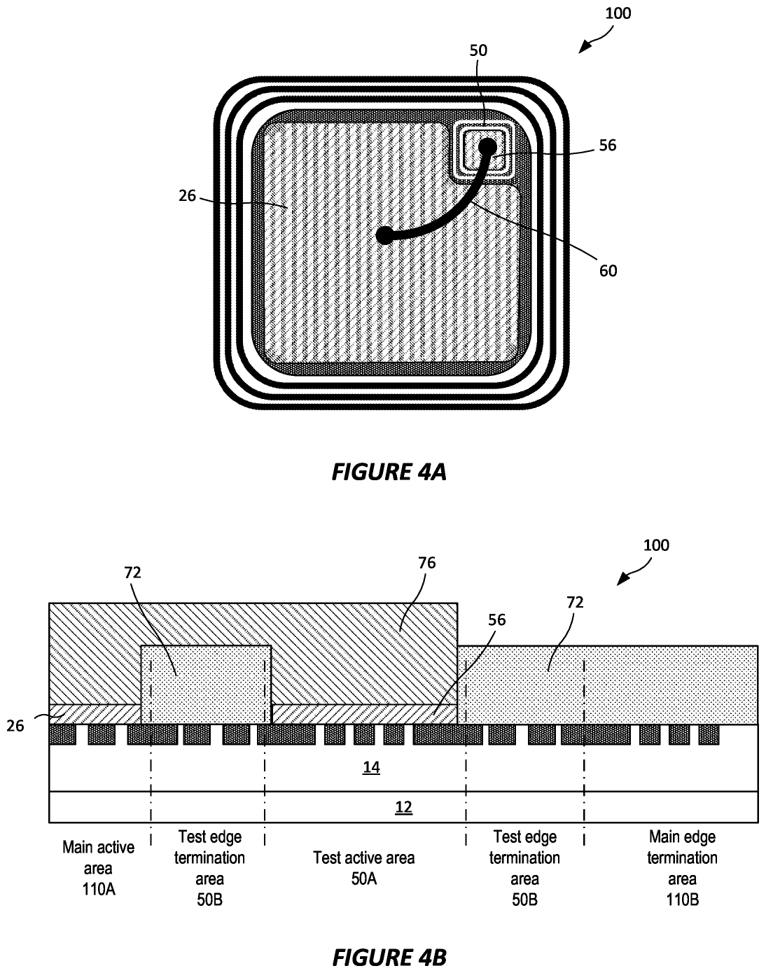

In some embodiments, after final test, the test anode contact 56 may be connected to the main anode contact 26 so that the test active area 50B under the anode test anode contact 56 can also be added to the functional device. If the inline test on the integrated test structure 50 is guaranteed not to damage the test structure 50, or verified not to have damaged it, then during packaging, the test anode contact 56 of the surge test device can be electrically connected to the main anode contact 26. For a 1200V 50A device, the added complexity may not be worth the gain of 0.8% (active area ratio)-1% (die area ratio), but for a 1200V 5A device, the test anode contact 56 may consume about 10% of the total die area, and so connecting it to the main anode contact 26 at the package level may be valuable. FIG. 4A illustrates an embodiment in which the test anode contact 56 is connected to the main anode contact 26 via a wirebond 60.

In some embodiments, such as when the Schottky diode device is integrated with another electronic device, such as a metal-oxide semiconductor field effect transistor (MOSFET), the test anode contact 56 may be electrically connected to the main anode contact 26 via a separate metal layer. For example, FIG. 4B is a cross sectional view showing a structure in which an interlayer dielectric layer 72 is formed on the upper surface of the device. In the embodiment illustrated in FIG. 4B, the interlayer dielectric layer 72 covers the test edge termination area 50B and the main edge termination area 110B. However, in some embodiments, the interlayer dielectric layer 72 may only cover the main edge termination area 110B. An overmetal layer 76 is formed on the device to electrically contact both the main anode contact 26 and the test anode contact 56 through openings in the interlayer dielectric layer 72.

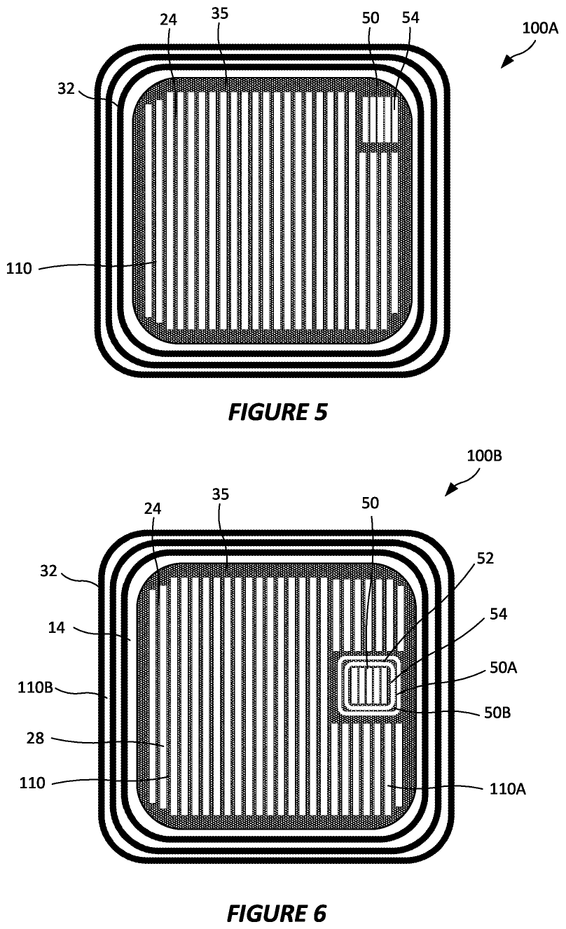

FIG. 5 illustrates a further embodiment of a Schottky diode structure 100A in which the integrated test structure 50 is formed in the same implanted well region 35 as the main Schottky diode 110, and is not separated from the main Schottky diode 110 by a test edge termination area. That is, the test anode contact 56 is a separate metal pad from the main anode contact 26. An advantage of this embodiment, which may be especially relevant for lower area devices, is that less area is lost, since no area is dedicated to isolation rings between the main active area 110A and the test active area 50A. A disadvantage of this embodiment is that the current at which integrated test structure 50 will have to be tested and its relationship with the surge capability of main Schottky diode 110 may not be straightforward, since current will spread through the shared p+ well 35 to the main Schottky diode device 110 even when the current is forced into the test anode contact 56. Additionally, if the integrated test structure 50 is damaged or shorted during testing, that will damage the whole device, so it would not be possible to classify the main device as a “low surge yet still usable per datasheet” device.

It will be appreciated that the integrated test structure 50 may be formed in various places within the main active area 110A of the Schottky diode structure 100 depending on design requirements. In particular, to facilitate wire bonding, it may be preferable to position the integrated test structure 50 near a corner of the main active area 110A (as shown in FIG. 2A) or near an edge of the main active area. For example, FIG. 6 illustrates a further embodiment of a Schottky diode structure 100B in which the integrated test structure 50 is formed along a side of the main active area 110A.

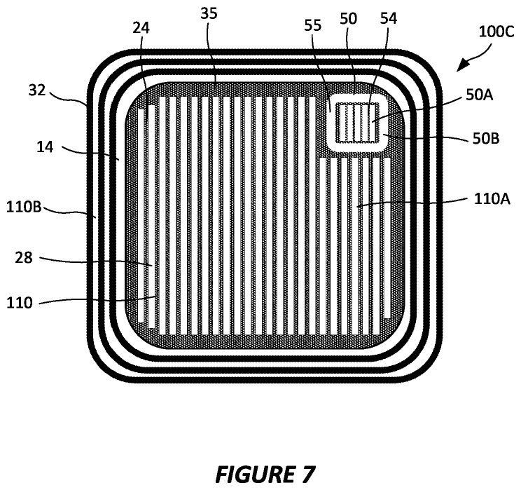

FIG. 7 illustrates a further embodiment of a Schottky diode structure 100C in which the test edge termination area 50B of the integrated test structure 50 only includes a single isolation ring 55 of non-implanted material to isolate the integrated test structure 50 from the main active area 110A. An isolation ring 55 may be provided instead of one or more floating guard rings because the integrated test structure 50 may not be subjected to high reverse voltages by itself during testing, and therefore may not need to have a separate edge termination.

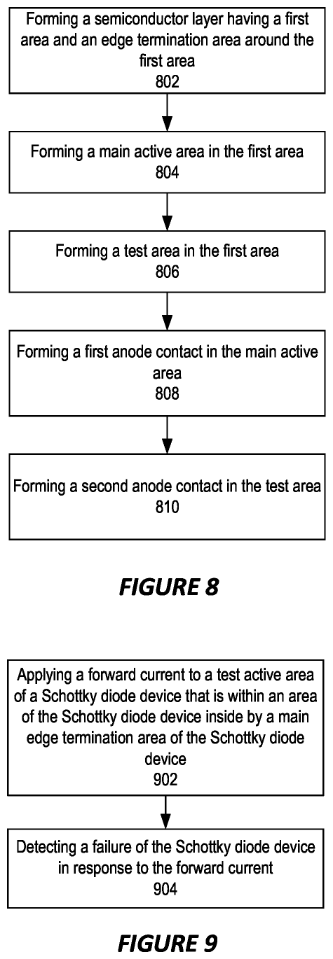

FIG. 8 illustrates operations for forming a Schottky diode according to some embodiments. In particular, a method of manufacturing a semiconductor device according to some embodiments includes forming a semiconductor layer comprising a first area and an edge termination area outside the first area (block 802). The semiconductor layer has a first conductivity type.

A main active area is formed within the first area (block 804). The main active area includes a first plurality of junction shielding regions in the semiconductor layer that have a second conductivity type opposite the first conductivity type.

The method further includes forming a test active area within the first area (block 806). The test active area includes a second plurality of junction shielding regions in the semiconductor layer.

The method further includes forming a first anode contact on the semiconductor layer in the main active area (block 808), and forming a second anode contact on the semiconductor layer in the test active area (block 810). The first anode contact contacts the semiconductor layer and the first plurality of junction shielding regions, the second anode contact contacts the semiconductor layer and the second plurality of junction shielding regions.

FIG. 9 illustrates operations for testing a Schottky diode according to some embodiments. Referring to FIG. 9, a method of testing surge current capability of a Schottky diode device according to some embodiments includes applying a forward current that is smaller than a maximum forward current of the Schottky diode device to a test active area that is within an area inside a main edge termination area of the Schottky diode device (block 902), and detecting a failure of the Schottky diode device in response to the forward current (block 904).

The Schottky diode device may have an edge termination area outside the main active area, and the test active area may be in an area inside the edge termination area.

The forward current may be applied to the test active area for a predetermined time period, and a level of the forward current may be selected based on a ratio of an area of the test active area to an area of the main active area and based on a rated operating current of the main active area.

It will be understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-section illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Although embodiments of the inventive concepts have been described in considerable detail with reference to certain configurations thereof, other versions are possible. Accordingly, the spirit and scope of the invention should not be limited to the specific embodiments described above.

What is claimed is:

1. A semiconductor device, comprising:
a semiconductor layer (14) comprising a first area (120) and an edge termination area (110B) outside the first area, wherein the semiconductor layer has a first conductivity type;
an active area (110A) in the first area;
a test area (50A) in the first area adjacent the active area;
a first anode contact (26) on the semiconductor layer in the active area;
a second anode contact (56) on the semiconductor layer in the test area; and
a cathode contact (22) in electrical contact with the semiconductor layer.

2. The semiconductor device of claim 1, wherein the active area comprises a first plurality of junction shielding regions (24) in the semiconductor layer, the first plurality of junction shielding regions having a second conductivity type opposite the first conductivity type;
wherein the first anode contact contacts the semiconductor layer and the first plurality of junction shielding regions.

3. The semiconductor device of claim 2, wherein the test area comprises a second plurality of junction shielding regions (54) in the semiconductor layer, wherein the second anode contact contacts the semiconductor layer and the second plurality of junction shielding regions.

4. The semiconductor device of claim 2, wherein the semiconductor layer comprises an n-type semiconductor material, and wherein the first plurality of junction shielding regions comprise p-type semiconductor areas.

5. The semiconductor device of claim 1, wherein the edge termination area comprises a main edge termination area, the semiconductor device further comprising a test edge termination area (50B) outside the test area, wherein the test edge termination area is within the first area.

6. The semiconductor device of claim 5, wherein the test edge termination area comprises a plurality of concentric rings of implanted regions having a second conductivity type, opposite the first conductivity type.

7. The semiconductor device of claim 6, wherein a spacing between adjacent ones of the plurality of concentric rings is non-uniform.

8. The semiconductor device of claim 7, wherein the spacing between adjacent ones of the plurality of concentric rings is greater in a middle portion of the test edge termination area and smaller in first portions of the test edge termination area near the active area and second portions of the test edge termination area near the test area.

9. The semiconductor device of claim 1, further comprising a conductive electrical connection between the first anode contact and the second anode contact.

10. The semiconductor device of claim 9, wherein the conductive electrical connection comprises a wirebond.

11. The semiconductor device of claim 9, wherein the conductive electrical connection comprises a metal layer.

12. The semiconductor device of claim 1, wherein the first area has a generally rectangular shape, and wherein the test active area is located near a corner of the first area.

13. The semiconductor device of claim 1, wherein the first area has a generally rectangular shape, and wherein the test area is located near a middle of a side of the first area.

14. The semiconductor device of claim 1, further comprising an isolation ring outside the test area, wherein the isolation ring comprises a region of the semiconductor layer having the first conductivity type.

15. The semiconductor device of claim 1, wherein the semiconductor device comprises a Schottky diode device or a metal-oxide semiconductor device.

16. A method of manufacturing a semiconductor device, comprising:
forming an edge termination area (110B) in a semiconductor layer (140), wherein the edge termination area is outside a first area of the semiconductor layer, wherein the semiconductor layer has a first conductivity type;
forming an active area (110A) in the first area;
forming a test area (50A) in the first area adjacent the active area;
forming a first anode contact (26) on the semiconductor layer in the active area;
forming a second anode contact (56) on the semiconductor layer in the test area; and
forming a cathode contact (22) in electrical contact with the semiconductor layer.

17. The method of claim 16, further comprising:
forming a first plurality of junction shielding regions (24) in the semiconductor layer, the first plurality of junction shielding regions having a second conductivity type opposite the first conductivity type;
wherein the first anode contact contacts the semiconductor layer and the first plurality of junction shielding regions.

18. The method of claim 17, further comprising:
forming a second plurality of junction shielding regions (54) in the semiconductor layer in the test area, wherein the second anode contact contacts the semiconductor layer and the second plurality of junction shielding regions.

19. The method of claim 16, wherein the semiconductor layer comprises an n-type semiconductor material, and wherein the junction shielding regions comprise p-type semiconductor areas.

20. The method of claim 16, wherein the edge termination area comprises a main edge termination area, the method further comprising forming a test edge termination area outside the test area, wherein the test edge termination area is within the area inside the main edge termination area.

21. The method of claim 20, wherein the test edge termination comprises a plurality of concentric rings of implanted areas having the second conductivity type.

22. The method of claim 21, wherein a spacing between adjacent ones of the plurality of concentric rings is non-uniform.

23. The method of claim 22, wherein the spacing between adjacent ones of the plurality of concentric rings is greater in a middle portion of the test edge termination area and smaller in first portions of the test edge termination area near the main active area and second portions of the test edge termination area near the test active area.

24. The method of claim 16, further comprising forming a conductive electrical connection between the first anode contact and the second anode contact.

25. The method of claim 24, wherein the conductive electrical connection comprises a wirebond.

26. The method of claim 24, wherein the conductive electrical connection comprises a metal layer.

27. The method of claim 16, wherein the first area has a generally rectangular shape, and wherein the test area is located near a corner of the first area.

28. The method of claim 16, wherein the first area has a generally rectangular shape, and wherein the test area is located near a middle of a side of the first area.

29. The method of claim 16, further comprising forming an isolation ring outside the test area, wherein the isolation ring comprises a area of the semiconductor layer having the first conductivity type.

30. The method of claim 16, wherein the semiconductor device comprises a Schottky diode device or a metal-oxide semiconductor device.

31. A method of testing surge current capability of a semiconductor device, comprising:
applying a forward current that is smaller than a maximum forward current of the semiconductor device to a test active area that is within an area inside a main edge termination area of the semiconductor device; and
detecting a failure of the semiconductor device in response to the forward current.

32. The method of claim 31, wherein the semiconductor device has an edge termination area outside the main active area, and wherein the test active area is in an area inside the main edge termination area.

33. The method of claim 32, wherein the forward current is applied to the test active area for a predetermined time period, wherein a level of the forward current is selected based on a ratio of an area of the test active area to an area of the main active area and based on a rated operating current of the main active area.

34. The method of claim 31, wherein the semiconductor device comprises a Schottky diode device or a metal-oxide semiconductor device.
